(19) United States
(12) Patent Application Publication
(10) Pub. No.: US 2025/0077221 A1
(43) Pub. Date: Mar. 6, 2025

(54) METHOD AND APPARATUS FOR UPDATING VEHICLE SOFTWARE USING AMOUNT OF ACCUMULATED CURRENT

(71) Applicants: HYUNDAI MOTOR COMPANY, Seoul (KR); KIA CORPORATION, Seoul (KR)

(72) Inventors: Keyng Bin IM, Asan-si (KR); Sung Tae KIM, Suwon-si (KR); Myoung Soo PARK, Yongin-si (KR)

(21) Appl. No.: 18/821,176

(22) Filed: Aug. 30, 2024

(30) Foreign Application Priority Data
Aug. 30, 2023 (KR) 10-2023-0114866

(51) Int. Cl. G06F 8/65; G01R 31/36

(52) U.S. Cl. CPC G06F 8/65; G01R 31/36

(57) ABSTRACT

A method for updating vehicle software can include: receiving a request for an update of vehicle software, determining whether a state of charge (SOC) of a vehicle battery can be calculated, determining, based on a determination that the SOC of the vehicle battery can be calculated, whether the vehicle software can be updated according to a value obtained by subtracting an expected amount of discharge from a current capacity of a battery being greater than a predetermined amount of energy, determining, based on a determination that the SOC of the vehicle battery cannot be calculated, whether the vehicle software can be updated according to an amount of accumulated current being greater than the expected amount of discharge and updating, based on a determination that the vehicle software can be updated and the vehicle engine being turned off, the vehicle software according to a remaining capacity of the vehicle battery.

### CROSS-REFERENCE TO RELATED APPLICATIONS

This application claims the benefit of Korean Patent Application No. 10-2023-0114866, filed on Aug. 30, 2023, which application is hereby incorporated herein by reference.

### TECHNICAL FIELD

The present disclosure relates to a method and an apparatus for updating vehicle software based on the amount of accumulated current, and, more particularly, to a method and an apparatus for updating vehicle software through the Over The Air (OTA) by comparing the amount of accumulated current of a vehicle with the expected amount of OTA discharge when it is not possible to calculate the state of charge (SOC) of a battery mounted on the vehicle.

### BACKGROUND

With the recent development of electronic technology, the use of electric control units (ECUs) for vehicles is becoming increasingly common, and software applied to vehicles is also developing quantitatively and qualitatively, becoming more complex. Accordingly, it is necessary to periodically update software applied to the ECUs in order to add new functions, correct errors, etc. in line with the changing electronic communication environment and technological developments. For such updates, vehicle manufacturers, ECU developers, etc. have performed updates of the ECUs offline, which is time-consuming and inconvenient because the driver of a vehicle have to travel to a location where the update is possible.

Meanwhile, as there is a growing need to immediately update various functions of vehicles equipped with cutting-edge functions, such as smart cars, self-driving cars, and connected cars, which are being commercialized as the technology has been recently developed, the ECUs are being updated through update-specific software installed in a vehicle's information system based on the Over The Air (OTA) technology to perform updates online. The OTA is a technology to update software in real time through wireless communication technology. When the OTA is applied to a vehicle, the vehicle can be upgraded to have the latest features by adding new functions such as real-time information provided by a navigation system and sound effects, fixing errors, etc. without a separate reservation, USB connection, etc. The OTA is used to improve functions to assist drivers, such as functions to avoid lane departure and a car crash or autonomous driving functions. With the OTA, security updates can be performed to prevent hacking attacks.

Updating vehicle software through the OTA consumes power from a vehicle battery. Accordingly, when vehicle software is updated through the OTA, the state of charge (SOC) of the vehicle's battery has to be taken into account. When it is not possible to calculate the SOC of a vehicle's battery, it is necessary to determine whether updating the vehicle's software is possible.

### SUMMARY

According to one aspect of the present disclosure, a method for updating vehicle software can include: receiving a request regarding a vehicle software update, determining whether a state of charge (SOC) of a vehicle battery can be calculated, determining, based on a determination that the SOC of the vehicle battery can be calculated, whether the vehicle software can be updated according to a value obtained by subtracting an expected amount of discharge from a current capacity of a battery being greater than a predetermined amount of energy, determining, based on a determination that the SOC of the vehicle battery cannot be calculated, whether the vehicle software can be updated according to an amount of accumulated current being greater than the expected amount of discharge and updating, based on a determination that the vehicle software can be updated and a vehicle engine being turned off, the vehicle software according to a remaining capacity of the vehicle battery, wherein, the expected amount of discharge is an amount of energy required to update the vehicle software.

According to another aspect of the present disclosure, an apparatus configured to update vehicle software can include: a memory storing instructions and at least one processor configured to execute the instructions to perform operations comprising, receiving a request regarding a vehicle software update, determining whether a state of charge (SOC) of a vehicle battery can be calculated, determining, based on a determination that the SOC of the vehicle batter can be calculated, whether the vehicle software can be calculated according to a value obtained by subtracting an expected amount of discharge from a current capacity of a battery being greater than a predetermined amount of energy, determining, based on a determination that the SOC of the vehicle battery cannot be calculated, whether the vehicle software can be updated according to an amount of accumulated current being greater than the expected amount of discharge, and updating, based on a determination that the vehicle software can be updated and the vehicle engine being turned off, the vehicle software according to a remaining capacity of the vehicle battery, wherein, the expected amount of discharge is an amount of energy required to update the vehicle's software.

### BRIEF DESCRIPTION OF THE DRAWINGS

FIG. 1 is a diagram illustrating an example of a controlling apparatus mounted on a vehicle.

FIG. 2 is a diagram illustrating an example of a process of determining whether the OTA update of vehicle software is possible.

FIG. 3 is a diagram illustrating an example of a map for calculating the amount of accumulated current.

FIG. 4 is a diagram illustrating an example of a method of determining whether the OTA update of vehicle software based on the amount of accumulated current is possible.

### DETAILED DESCRIPTION

The present disclosure provides a method and an apparatus for determining whether the OTA update of vehicle software can be performed based on the amount of accumulated current.

In addition, the present disclosure provides a method and an apparatus for calculating the amount of accumulated current based on a charging voltage and the temperature of battery liquid.

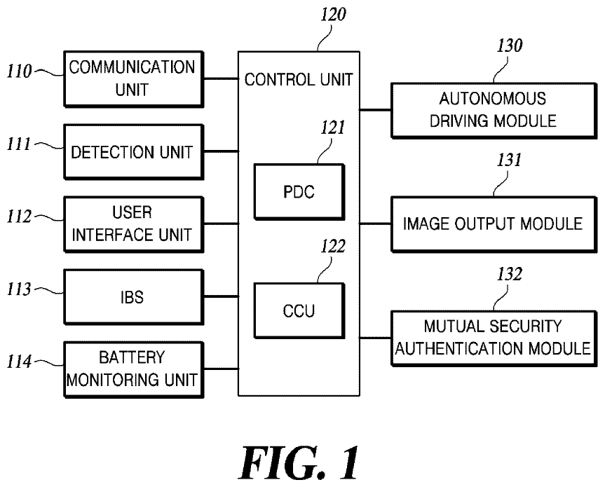

FIG. 1 is a diagram for describing a controlling apparatus mounted on a vehicle.

Referring to FIG. 1, an autonomous vehicle may include a communication unit 110, a detection unit 111, a user interface unit 112, an intelligent battery sensor (IBS) 113, a battery monitoring unit 114, a control unit 120, an autonomous driving module 130, an image output module 131, and a mutual security authentication module 132. The communication unit 110 may transmit and receive information through a communication network between autonomous vehicles and between autonomous vehicles and other objects. The communication unit 110 may transmit and receive information between autonomous vehicles and between autonomous vehicles and other objects through at least one of wireless LAN, Wireless-Fidelity (Wi-Fi), Wireless Fidelity (Wi-Fi) Direct, Digital Living Network Alliance (DLNA), Wireless Broadband (WiBro), World Interoperability for Microwave Access (WiMAX), High Speed Downlink Packet Access (HSDPA), High Speed Uplink Packet Access (HSUPA), Long Term Evolution (LTE), and Long Term Evolution-Advanced (LTE-A).

In addition, the communication unit 110 may perform short-distance communication between autonomous vehicles and between autonomous vehicles and other objects. Because autonomous vehicles maintain a short distance from each other while driving, the communication unit 110 may transmit and receive information between autonomous vehicles and between autonomous vehicles and other objects through short-range wireless communication. In this case, by the communication unit 110, various information between autonomous vehicles and between autonomous vehicles and other objects may be transmitted and received through Bluetooth, Radio Frequency Identification (RFID), Infrared Data Association (IrDA), Ultra-Wide Band (UWB), ZigBee, Near Field Communication (NFC), Wireless-Fidelity (Wi-Fi), Wi-Fi Direct, Wireless Universal Serial Bus (Wireless USB), etc.

The detection unit 111 may include a radar, a camera, a lidar, etc. The detection unit 111 may determine the speed and the position of nearby autonomous vehicles and objects, etc. The detection unit 111 may detect all objects such as obstacles, people, animals, toll booths, and breakwaters, in addition to autonomous vehicles. The user interface unit 112 may provide a user interface for a driver. The user interface unit 112 may input information received from a driver into the control unit 120 or output results of the operation. For example, the driver may input information about nearby autonomous vehicles and objects into the user interface unit 112. The user interface unit 112 may input information about nearby autonomous vehicles and objects into the control unit 120. The control unit 120 may issue a control command to the autonomous driving module 130 based on information about nearby autonomous vehicles and objects.

The IBS 113 may correspond to a sensor for reading information about the state of a battery. The IBS 113 may measure the current, the voltage, etc. of a battery in real time. The IBS 113 may measure the amount of battery charge based on the current, the voltage, etc. of a battery. The IBS 113 may measure the state of charge (SOC) of a battery and transmit information thereon to the battery monitoring unit 114 and the user interface unit 112. The measured SOC of the battery may be displayed on the user interface unit 112. The SOC of a battery may be calculated as a percentage value by an open circuit voltage (OCV) when the current of the battery is stabilized and maintained for a certain period of time. When the current of a battery is continuously measured, the IBS 113 may calculate the SOC of the battery based on the accumulated current.

When calculating the SOC of a battery through the OCV fails because the current of the battery is continuously excessive, the user interface unit 112 may display the SOC of the battery as a value of 255. When a vehicle's battery is discharged, the user interface unit 112 may display the SOC of the battery as a value of 255. For example, a vehicle's battery may be discharged due to power consumption by the vehicle's dashcam. For example, a vehicle having a dashcam operates by being connected to a 12V lead-acid battery and may thus frequently generate battery consumption current. Accordingly, the conditions for the IBS 113 to learn the SOC of a battery are not met, so the IBS 113 may remain untrained. When the IBS 113 remains untrained, the user interface unit 112 may display the SOC of a battery as a value of 255.

The IBS 113 mounted on a vehicle battery for supplying power to a vehicle may measure the current state of the battery. The IBS 113 may measure the SOC, the state of health (SOH), and the state of function (SOF) of a battery by measuring the voltage, the current, and the temperature of the battery. The battery monitoring unit 114 may monitor the SOC, the SOH, and the SOF of a battery. The battery monitoring unit 114 may store information on the SOC, the SOH, and the SOF of a battery, which has been input by the IBS 113. The SOC may indicate how much a battery is currently charged compared to its full charge, and the SOH may indicate how old the battery is compared to new one. The SOF may indicate how well a battery's performance meets actual requirements while the battery is in use, and may be determined by the battery's SOC, SOH, operating temperature, and charge/discharge history.

Based on information received from the communication unit 110, the detection unit 111, the user interface unit 112, the IBS 113, and the battery monitoring unit 114, the control unit 120 may control the autonomous driving module 130, the image output module 131, and the mutual security authentication module 132.

The control unit 120 may include a trained learning model. The learning model may correspond to a model based on deep learning. The control unit 120 may additionally include a learning unit to train a learning model in advance. The learning unit may train a learning model in advance based on supervised learning, unsupervised learning, semi-supervised learning, and/or reinforcement learning. Here, it is well known in the field how a learning unit trains a learning model based on learning data, so a detailed description thereof will not be provided herein.

The control unit may include a power domain controller (PDC) 121 and a central communication unit (CCU) 122. The PDC 121 may correspond to a main controller that determines the state of power. The PDC 121 may determine the current state of power of a vehicle based on battery information received from the IBS 113. The PDC 121 may calculate the expected amount of the over the air (OTA) discharge based on information about the OTA update of vehicle software received from the CCU 122. The CCU 122 may correspond to a controller for managing a communication gateway and the OTA update of vehicle software. The CCU 122 may perform updates, downloads, background transmission, etc. of vehicle software. The CCU 122 may transmit information about the time taken for the OTA update of vehicle software to the PDC 121.

The CCU 122 may determine whether to perform the OTA update of vehicle software based on the result of the determination on the state of power by the PDC 121. A battery may be charged while the vehicle is driving, taking the OTA into account. When a vehicle is parked, software of the vehicle may be updated using the charged power from the battery that has been secured in advance while the vehicle is driving. When a request for the OTA update of vehicle software occurs, a vehicle may carry out full charging to charge the battery sufficiently. A generator may not perform variable voltage control to improve fuel efficiency, but may use high generated voltage to fully charge the battery. For example, the generator may correspond to a low voltage DC-DC converter (LDC), an alternator, etc.

The autonomous driving module 130 may change or maintain the speed, the direction, etc. of a vehicle according to control commands from the control unit 120. The image output module 131 may output images of nearby vehicles, obstacles, buildings, etc. for a driver according to control commands from the control unit 120. The mutual security authentication module 132 may perform authentication based on identifiers (IDs) between nearby vehicles and between nearby objects according to control commands from the control unit 120. Such an authentication may be performed through UWB. Autonomous vehicles can defend against spoofing attacks by attackers through the authentication.

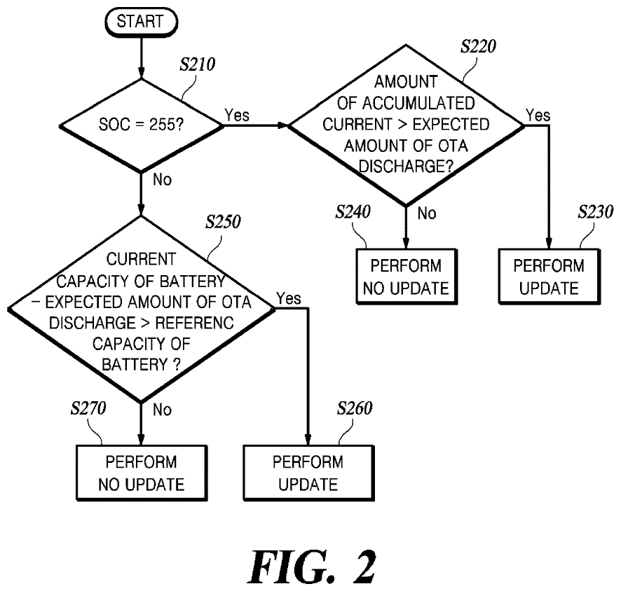

FIG. 2 is a diagram for illustrating a process of determining whether the OTA update of vehicle software is possible.

Referring to FIG. 2, the control unit may monitor whether a request for the OTA update of vehicle software has occurred. When the request for the OTA update of vehicle software has occurred, it may be determined whether the vehicle's engine is turned on. It may be determined whether the vehicle's engine is turned on to charge the battery for the OTA update of vehicle software. The battery may be charged while a vehicle is driving. Such a battery may correspond to a 12V lead-acid battery.

When a request for the OTA update of vehicle software has occurred, it may be determined whether the user interface unit displays the SOC of a vehicle as 255 at S210. When the SOC of the vehicle is displayed as 255 (YES at S210), the PDC may determine whether the amount of accumulated current is greater than the expected amount of OTA discharge at S220. When the SOC of a vehicle is displayed as 255, the IBS may have failed to calculate the SOC. When the amount of accumulated current is greater than the expected amount of OTA discharge (YES at S220), the OTA update of vehicle software may be performed at S230. When a vehicle's engine is turned off, the OTA update may be carried out.

The CCU may perform updates of vehicle software. The PDC may calculate the amount of accumulated current and the expected amount of OTA discharge. The amount of accumulated current may be accumulatively calculated based on the map while a vehicle is running. The expected amount of OTA discharge may be calculated by summing the expected time required to update each controller for the event of updating vehicle software. The expected amount of OTA discharge may be calculated by multiplying the expected time required to update each controller by the value of discharge current. For example, when updates of vehicle software are performed on three electric control units (ECUs), the time required to update the software of each of the three ECUs may be sufficiently secured in advance through experimentation. Accordingly, when the targets on which updates of vehicle software will be performed are determined, the expected amount of OTA discharge required for the software update may be calculated.

When the amount of accumulated current is not greater than the expected amount of OTA discharge (NO at S220), the OTA update may not be performed at S240. The PDC may transmit information on whether the OTA update is possible to the CCU. When the engine of a vehicle can be turned on and the amount of accumulated current is greater than the expected amount of OTA discharge at the time point when the amount of accumulated current is compared with the expected amount of OTA discharge, it may be determined that the engine can be turned on even after the OTA update.

When the SOC of a vehicle is not displayed as 255 (NO at S210), the PDC may determine whether the value obtained by subtracting the expected amount of OTA discharge from the current capacity of the vehicle battery is greater than the reference battery capacity at S250. The IBS may continuously transmit information about the state of a battery to the PDC. The reference battery capacity may correspond to a value predetermined based on the operation of a vehicle. The reference battery capacity may correspond to the amount of energy required to turn on a vehicle. The reference battery capacity may correspond to the amount of energy calculated based on the reference SOC. The current capacity of a vehicle battery may correspond to the amount of remaining energy calculated based on the current SOC. When the value obtained by subtracting the expected amount of OTA discharge from the current capacity of a vehicle battery is greater than the reference battery capacity (YES at S250), the OTA update may be performed at S260. When a vehicle's engine is turned off, the OTA update may be performed. When the value obtained by subtracting the expected amount of OTA discharge from the current capacity of a vehicle battery is not greater than the reference battery capacity (NO at S250), the OTA update may not be performed at S270. The PDC may transmit information about whether the OTA update is possible to the CCU. The unit of battery capacity, energy amount, and expected amount of discharge may be Ah.

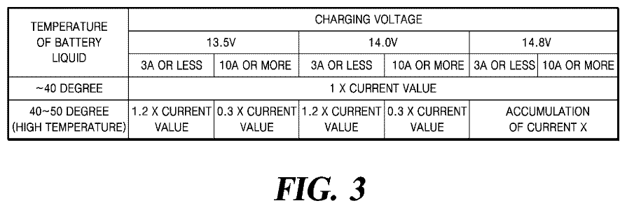

FIG. 3 is a diagram for describing a map for calculating the amount of accumulated current. The OTA update of vehicle software may be divided into the process of receiving the data necessary for the update and the process of performing necessary updates based on the received data. The reception of the data required for the update may be carried out when a vehicle's engine has been turned on, and the update of the vehicle software may be performed when the operation of the vehicle has been finished and the engine has been turned off. This is because the vehicle software is in use while the vehicle is in operation so that it is not possible to update the vehicle software. Less power may be required for the reception of the data necessary for the update of vehicle software, but the update of the vehicle software may consume more power because it has to be performed after relevant devices are electrically activated.

Therefore, while a vehicle is in operation, sufficient power required for the update of vehicle software may be secured in advance. When the operation of the vehicle has been finished and the vehicle's engine has been turned off, the update of the vehicle software may be performed using the sufficient power secured in advance. When sufficient power is not secured during one driving, current may be continuously accumulated during a later driving to secure more power.

The PDC may calculate the amount of accumulated current based on the temperature and the charging voltage of battery liquid. The amount of current secured while driving of a vehicle may depend on how aged the vehicle's battery is. When an old battery is charged with the same voltage, the value of charging current may be lower. For example, when a new battery is charged with 14.8V and the value of charging current is A, the measured value of the charging current may be A. For example, an aging battery is charged with 14.8V and the value of charging current is A, the measured value of the charging current may be 0.3×A. A vehicle's battery may be protected by changing a charging voltage depending on the temperature of battery liquid. A chemical reaction may be made quickly when the temperature of battery liquid is high, so that the value of a battery's charging current may increase when the battery is charged with the same voltage, resulting in lower durability of the battery. When the temperature of battery liquid is high, a vehicle may be controlled to allow the vehicle's battery to be charged with a low voltage. When a charging current is accumulated based on such characteristics of batteries, the amount of accumulated current may be calculated based on the map.

Referring to FIG. 3, when the temperature of battery liquid is 30 degrees and the value of the battery's charging voltage is 13.5V, current may accumulate as much as the measured value of charging current. When the temperature of battery liquid is 30 degrees and the value of the battery's charging voltage is 14V, current may accumulate as much as the measured value of charging current. When the temperature of battery liquid is 30 degrees and the value of the battery's charging voltage is 14.8V, a current of 1 time the measured charging current may be accumulated.

With battery liquid's temperature of 45 degrees, the battery's charging voltage of 13.5V, and the charging current of 3 A or less, a current of 1.2 times the measured charging current may be accumulated. With battery liquid's temperature of 45 degrees, the battery's charging voltage of 13.5V, and the charging current of 10 A or more, a current of 0.3 time the measured charging current may be accumulated. With battery liquid's temperature of 45 degrees, the battery's charging voltage of 14V, and the charging current of 3 A or less, a current of 1.2 times the measured charging current may be accumulated. With battery liquid's temperature of 45 degrees, the battery's charging voltage of 14V, and the charging current of 10 A or more, a current of 0.3 time the measured charging current may be accumulated. With battery liquid's temperature of 45 degrees and the battery's charging voltage of 14.8V, no measured charging current may be accumulated.

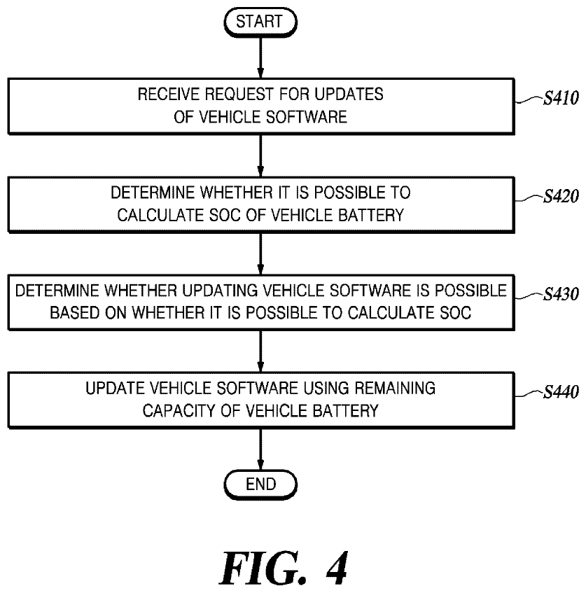

FIG. 4 is a diagram for describing a method of determining whether the OTA update of vehicle software based on the amount of accumulated current is possible.

Referring to FIG. 4, an apparatus for updating vehicle software may receive a request for updates of vehicle software at S410. The apparatus for updating vehicle software may update vehicle software through the OTA. The apparatus for updating vehicle software may determine whether the SOC of a vehicle battery can be calculated at S420. A vehicle battery may be charged while the vehicle is running. The apparatus for updating vehicle software may determine whether the vehicle software can be updated based on whether it is possible to calculate the SOC at S430.

When the SOC can be calculated, the apparatus for updating vehicle software may determine whether the value obtained by subtracting the expected amount of discharge from the current capacity of a battery is greater than a predetermined amount of energy to determine whether updating vehicle software is possible. When it is not possible to calculate the SOC, the apparatus for updating vehicle software may determine whether the amount of accumulated current is greater than the expected amount of discharge to determine whether updates of vehicle software is possible. The expected amount of discharge may correspond to the amount of energy required to update vehicle software. The value of the predetermined amount of energy may correspond to the value required to turn on the engine of a vehicle. The expected amount of discharge may be calculated by multiplying the value of discharge current by the time taken to update vehicle software. The amount of accumulated current may correspond to the amount of current secured while a vehicle is running. The amount of accumulated current may be calculated based on the map, the temperature of the vehicle's battery liquid, a charging voltage, and a charging current. The amount of accumulated current may be calculated by multiplying the value of a charging current by a weight based on the range of the temperature of the vehicle's battery liquid and the range of the charging current.

When it is possible to update vehicle software and the engine of the vehicle is turned off, the apparatus for updating vehicle software may update vehicle software based on the remaining capacity of the vehicle battery at S440.

According to the present disclosure, it may be possible to determine whether the OTA update of vehicle software is possible when a battery sensor has not learned the SOC.

In addition, according to the present disclosure, it may be possible to determine whether the OTA update of vehicle software is possible when calculating the SOC is not possible.

The effects to be obtained by the present disclosure are not limited to the effects mentioned above, and other effects not mentioned will be clearly understood by those skilled in the art from the description below.

Each element of the apparatus or method in accordance with the present disclosure may be implemented in hardware or software, or a combination of hardware and software. The functions of the respective elements may be implemented in software, and a microprocessor may be implemented to execute the software functions corresponding to the respective elements.

Various implementations of systems and techniques described herein can be realized with digital electronic circuits, integrated circuits, field programmable gate arrays (FPGAs), application specific integrated circuits (ASICs), computer hardware, firmware, software, and/or combinations thereof. The various implementations can include implementation with one or more computer programs that are executable on a programmable system. The programmable system includes at least one programmable processor, which may be a special purpose processor or a general-purpose processor, coupled to receive and transmit data and instructions from and to a storage system, at least one input device, and at least one output device. Computer programs (also known as programs, software, software applications, or code) include instructions for a programmable processor and are stored in a “computer-readable recording medium.”

The computer-readable recording medium may include all types of storage devices on which computer-readable data can be stored. The computer-readable recording medium may be a non-volatile or non-transitory medium such as a read-only memory (ROM), a compact disc ROM (CD-ROM), magnetic tape, a floppy disk, a memory card, a hard disk, or an optical data storage device. In addition, the computer-readable recording medium may further include a transitory medium such as a data transmission medium. Furthermore, the computer-readable recording medium may be distributed over computer systems connected through a network, and computer-readable program code can be stored and executed in a distributive manner.

What is claimed is:

1. A method performed by an apparatus configured to update vehicle software, the method comprising:
receiving a request regarding a vehicle software update;
determining whether a state of charge (SOC) of a vehicle battery can be calculated;
determining, based on a determination that the SOC of the vehicle battery can be calculated, whether the vehicle software can be updated according to a value obtained by subtracting an expected amount of discharge from a current capacity of a battery being greater than a predetermined amount of energy;
determining, based on a determination that the SOC of the vehicle battery cannot be calculated, whether the vehicle software can be updated according to an amount of accumulated current being greater than the expected amount of discharge; and
updating, based on (i) a determination that the vehicle software can be updated and (ii) a vehicle engine being turned off, the vehicle software according to a remaining capacity of the vehicle battery,
wherein the expected amount of discharge is an amount of energy required to update the vehicle software.

2. The method of claim 1, wherein the predetermined amount of energy is a value required to turn on the vehicle engine, and
wherein the amount of accumulated current is an amount of current charged while the vehicle engine is operating.

3. The method of claim 1, wherein the amount of accumulated current is calculated based on a map, and
wherein the amount of accumulated current is calculated based on a temperature of a vehicle battery liquid, a charging voltage, and a charging current.

4. The method of claim 3, wherein the amount of accumulated current is calculated by multiplying a value of the charging current by a weight based on a range of the temperature of the vehicle battery liquid and a range of the charging current.

5. The method of claim 1, wherein the expected amount of discharge is calculated by multiplying a value of discharge current by time taken to update the vehicle software.

6. An apparatus configured to update vehicle software, comprising:
a memory storing instructions; and
at least one processor configured to execute the instructions to perform operations comprising:
receiving a request regarding a vehicle software update,
determining whether a state of charge (SOC) of a vehicle battery can be calculated,
determining, based on a determination that the SOC of the vehicle batter can be calculated, whether the vehicle software can be calculated according to a value obtained by subtracting an expected amount of discharge from a current capacity of a battery being greater than a predetermined amount of energy,
determining, based on a determination that the SOC of the vehicle battery cannot be calculated, whether the vehicle software can be updated according to an amount of accumulated current being greater than the expected amount of discharge, and
updating, based on (i) a determination that the vehicle software can be updated and (ii) a vehicle engine being turned off, the vehicle software according to a remaining capacity of the vehicle battery,
wherein the expected amount of discharge is an amount of energy required to update the vehicle software.

7. The apparatus of claim 6, wherein the predetermined amount of energy is a value required to turn on the vehicle engine, and
wherein the amount of accumulated current is an amount of current charged while the vehicle engine is operating.

8. The apparatus of claim 6, wherein the amount of accumulated current is calculated based on a map, and
wherein the amount of accumulated current is calculated based on a temperature of a vehicle battery liquid, a charging voltage, and a charging current.

9. The apparatus of claim 8, wherein the amount of accumulated current is calculated by multiplying a value of the charging current by a weight based on a range of the temperature of the vehicle battery liquid and a range of the charging current.

10. The apparatus of claim 6, wherein the expected amount of discharge is calculated by multiplying a value of discharge current by time taken to update the vehicle software.
